(19) United States
(12) Patent Application Publication
(10) Pub. No.: US 2026/0122859 A1
(43) Pub. Date: Apr. 30, 2026

(54) SMART HOSE KIT FOR LIQUID COOLED RACKS

(71) Applicant: Microsoft Technology Licensing, LLC, Redmond, WA (US)

(72) Inventors: Yimin ZHANG, Johns Creek, GA (US); Xianfa ZHANG, Issaquah, WA (US); Andrew Douglas Delano, Woodinville, WA (US); David Gerard HOODMAN, Sammamish, WA (US); Jason Blake CHESSER, Colorado Springs, CO (US); Nehal MODY, Redmond, WA (US); John Jason BRZOZOWSKI, Schwenksville, PA (US); Nisha JOHN, Bothell, WA (US); Siddharth BHOPTE, Sammamish, WA (US); Guixiang Ellen TAN, Portland, OR (US)

(21) Appl. No.: 18/932,674

(22) Filed: Oct. 31, 2024

(51) Int. Cl. H05K 7/20

(52) U.S. Cl. CPC H05K 7/20627; H05K 7/20272; H05K 7/207

(57) ABSTRACT

The described technology provides a coolant system for a computing system rack, the coolant system including a hose configured to deliver coolant to and from a computing system rack, one or more sensors configured to measure one or more parameters of the coolant flowing through the hose and to communicate the one or more measured parameters to a hose controller, and an auto-valve configured on the hose to control the flow of coolant through the hose. The hose controller may be configured on the computing system rack and may be configured to control the auto-valve based on one or more of temperature of the coolant, flow level of the coolant, and pressure of the coolant.

### BACKGROUND

Modern computing systems including systems for providing artificial intelligence (AI) solutions typically process a large number of transactions and therefore consume high levels of power. As a result, such systems also generate excessive heat levels. With the increased chip power consumption and heat generation for such new AI platforms, traditional air-cooled server rack design cannot meet the cooling needs of new AI and cloud platforms. Therefore, liquid cooling is often employed for cooling the computing system racks. However, there are many challenges with liquid cooling as an it is an immature technology.

### SUMMARY

The described technology provides a coolant system for a computing system rack, the coolant system including a hose configured to deliver coolant to and from a computing system rack, one or more sensors configured to measure one or more parameters of the coolant flowing through the hose and to communicate the one or more measured parameters to a hose controller, and an auto-valve configured on the hose to control the flow of coolant through the hose. The hose controller may be configured on the computing system rack and may be configured to control the auto-valve based on one or more of temperature of the coolant, flow level of the coolant, and pressure of the coolant.

The above presents a simplified summary of the innovation in order to provide a basic understanding of some implementations described herein. This summary is not an extensive overview of the claimed subject matter. It is intended to neither identify key or critical elements of the claimed subject matter nor delineate the scope of the subject innovation. Its sole purpose is to present some concepts of the claimed subject matter in a simplified form as a prelude to the more detailed description that is presented later.

Other implementations are also described and recited herein.

### BRIEF DESCRIPTIONS OF THE DRAWINGS

Examples are illustrated in referenced figures of the drawings. It is intended that the examples and figures disclosed herein are to be considered illustrative rather than restrictive.

FIG. 1 illustrates an example implementation of a coolant system for a computing system rack.

FIG. 2 illustrates an alternative example implementation of the coolant system for the computing system rack.

FIG. 3 illustrates example operations of the cooling system disclosed herein.

FIG. 4 illustrates alternative example operations of the cooling system disclosed herein.

FIG. 5 illustrates an example computing system that may be used to implement the coolant management system disclosed herein.

### DETAILED DESCRIPTIONS

Modern computing systems including systems for providing artificial intelligence (AI) solutions typically process a large number of transactions and therefore consume high levels of power. As a result, such systems also generate excessive heat levels. With the increased chip power consumption and heat generation for such new AI platforms, traditional air-cooled server rack design cannot meet the cooling needs of new AI and cloud platforms. Therefore, liquid cooling is often employed for cooling the computing system racks. However, there are many challenges with liquid cooling as an it is an immature technology. The technology disclosed herein relates to providing a smart hose kit to address some of these challenges.

Specific implementations disclosed herein provides a coolant system for a computing system rack, the coolant system including a hose configured to deliver coolant to and from a computing system rack, one or more of (a) a temperature sensor to determine a temperature of the coolant flowing through the hose, (b) a flow sensor configured to determine flow level of the coolant flowing through the hose, a coolant leak sensor, and (d) a pressure sensor configured to determine pressure of the coolant flowing through the hose, and an auto-valve configured on the hose to control the flow of coolant through the hose. The hose controller may be configured on the computing system rack and may be configured to control the auto-valve based on one or more of the temperature of the coolant, the flow level of the coolant, and the pressure of the coolant.

An implementation of the coolant system disclosed herein provides a hose control kit that connects to coolant supply/return pipes, which in turn link to a cooling heat exchanger. The cooling heat exchanger may be a coolant distribution unit (CDU) that performs liquid-to-liquid heat exchange with a facility cooling water supply. Alternatively, the cooling heat exchanger may be liquid-to-air heat rejection unit (HRU).

Implementations of liquid cooled computing system racks (also referred to herein as information technology racks (IT racks)) also allow an IT rack is to isolate itself from other similar IT racks and the CDUs and HRUs in case of a coolant leak or a need to perform the services on the IT rack. Furthermore, the IT racks disclosed herein are aware of various flow parameters of the coolant flowing through the hose. For example, such coolant parameters include coolant flow rate, coolant temperature, coolant pressure, coolant viscosity, etc. A leak detector may be configured on the IT rack to communicate with the hose control kit, where the leak detectors monitor the IT rack for coolant leaks and communicates the coolant leak to the hose control kit.

In one implementation, various sensors of the hose control kit, such as the temperature sensor, the pressure sensor, and the flow rate sensor are placed on the hose. For example, one or more of these sensors may be placed on an elbow joint of the hose where such elbow joint connects the hose to the IT rack. The sensors may communicate the measured parameters, such as the coolant flow rate, coolant temperature, coolant pressure to a smart hose controller (SHC). In one implementation, the sensors communicate with the SHC wirelessly using a wireless communication protocol. For example, such wireless protocol may include Bluetooth, Bluetooth LE, ZigBee, Z-Wave, etc.

The SHC may be implemented on a smart hose controller (SHC) board. In one implementation, the SHC board is configured on an IT rack. Alternatively, the SHC board may be implemented outside the IT rack and adjacent to the hose. The SHC may be configured to receive the measured parameters, to analyze the measured parameters, and to control the auto-valve based on its analysis of the measured parameters. In one implementation, the SHC board received its power from the IT rack, and it also supplies power to the one or more sensors as well as to the auto-valve.

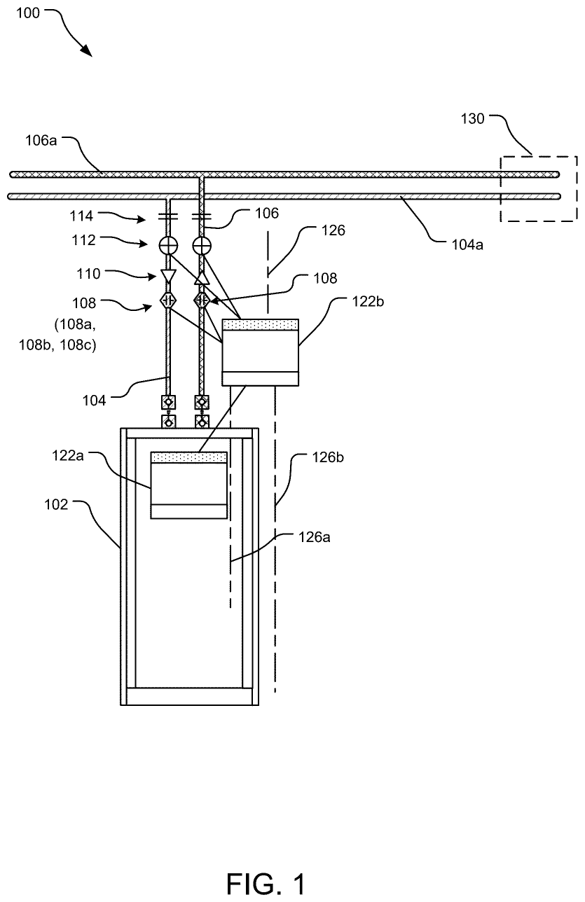

FIG. 1 illustrates an implementation of a coolant system 100 for a computing system rack. Specifically, the coolant system 100 includes a computing system rack (also referred to herein as an IT rack) 102 that is connected to an incoming hose 104 and an outgoing hose 106 (both the incoming hose 104 and the outgoing hose 106 together referred to herein as the hoses 104, 106). The incoming hose 104 is configured to supply a coolant to the IT rack 102 and the outgoing hose 106 may be used to return the coolant that is used to cool the IT rack. The incoming coolant in the incoming hose 104 may be cooled by a coolant distribution unit (CDU) 130. In one implementation, one CDU 130 may be used to cool one or more IT racks including the IT rack 102. However, in alternative implementation, there may be more than one CDUs 130 used for cooling a number of IT racks. Thus, for example, an implementation may include m CDUs for cooling n IT racks.

The incoming coolant in the incoming hose 104 is at a lower temperature than the outgoing coolant being returned to the CDU 130 via the outgoing hose 106. The IT rack 102 may include a mesh of cooling surfaces that are exposed to the coolant flowing through the hoses 104, 106. In one implementation, the IT rack 102 may also include cold plates that are placed under one or more chips of the IT rack 102 to provide cooling to such chips. Therefore, the cool temperature of the incoming coolant allows removing heat from the IT rack 102. In one implementation, one or more sensors 108 may be configured on the incoming hose 104 and/or the outgoing hose 106. For example, the sensors 108 may include a temperature sensor 108a, a pressure sensor 108b, and a flow rate sensor 108c. While in one implementation, both of the hoses 104 and 106 may be configured with each of the sensors 108, in alternative implementation only one set of sensors 108 may be provided. Thus, the incoming hose 104 may have each of the temperature sensor 108a, the pressure sensor 108b, and the flow rate sensor 108c, whereas the outgoing hose 106 may not include any sensors. Yet alternatively, some of the sensors 108 may be configured on the incoming hose 104 and the other of the sensors 108 may be configured on the outgoing hose 106.

The sensors 108 may collect parameters of the coolant flowing through the hoses 104, 106 on a continuous or periodic bases. For example, the temperature sensor 108a may be an analog sensor generating analog output of the temperature of the coolant passing through the hoses 104, 106 and it may be configured to communicate the temperature value to a smart hose controller (SHC) 122 on a periodic basis. Similarly, the pressure sensor 108b may be configured to measure the pressure of the flow of coolant in the hoses 104, 106 and communicate it to the SHC 122. On the other hand, the flow rate sensor 108c may be configured to measure the rate of the flow of coolant in the hoses 104, 106 and communicate it to the SHC 122. Additionally, the hoses 104, 106 may also be equipped with check valves 110, auto-valves 112, and flanges 114. The check valves 110 may be used to automatically shut-off back flow of the coolant in the hoses 104, 106. The check valves 110 are used to prevent back-flow of coolant in the hoses 104, 106, and the flanges 114 may be used to connect the hoses 104, 106 to the supply and return lines 104a, 106a coming from the CDU 130. The flanges 114 may be used to manually disconnect the hoses 104, 106 from the supply and return lines 104a, 106a.

In one implementation, the sensors 108 may be configured to communicate with the SHC 122 wirelessly using a wireless protocol. For example, such wireless protocols may include Bluetooth, Bluetooth LE, ZigBee, Z-Wave, etc. Alternatively, the sensors 108 may communicate the measured parameters to the SHC 122 using a wired connection.

In the illustrated implementation, the SHC 122 is illustrated as being configured on the IT rack 102, as shown by 122a. However, in an alternative implementation, the SHC 122 may be implemented close to the hoses 104, 106 and outside the IT rack 102, as shown by 122b. The SHC 122 may also be configured to receive power from the IT rack 102 and to provide power to one or more of the sensors 108 and the auto-valves 112. The SHC is configured to receive the parameter values from the sensors 108 and analyze the parameter values to make various decisions regarding the cooling operation of the IT rack and to change one or more operating parameters of the coolant flow through the hoses 104, 106.

For example, the SHC 122 may determine that the pressure of the coolant flowing through one or both of the hoses 104, 106 is too low. In which case, the SHC 122 may communicate with the CDU 130 to increase the coolant flow. Alternatively, the SHC 122 may decide to control the coolant pressure by managing the auto-valves 112. The SHC 122 may also calculate the differential values based on the parameter values generated by the sensors 108. For example, the SHC 122 may calculate the temperature differential between the temperature measured by the temperature sensor on the incoming hose 104 and the temperature measured by the outgoing hose 106 to determine the increase in coolant temperature as it passes through the IT rack 102. In one implementation, if such increase in coolant temperature is above a threshold, indicating higher temperatures in IT rack, the SHC 122 may communicate with the CDU 130 to further decrease the temperature of the incoming coolant in the incoming hose 104. Alternatively, if the increase in coolant temperature is above/below another threshold, the SHC 122 may determine that the IT rack is overutilized/underutilized and communicate this to a cloud system that may be managing the workload to the IT rack.

The coolant system 100 may also include leak detection rope 126 that is configured to monitor leak of coolant. For example, the leak detection rope 126 may be configured on the IT rack 102, as shown by 126a, such that it generates a signal in response to detection of coolant leak in the IT rack 102 and communicate such signal to the SHC 122. Additionally, the leak detection rope 126 may also be implemented outside the IT rack 102, as illustrated by 126b to detect any leak of coolant outside the IT rack 102 and to communicate detection of such a leak to the SHC 122. The SHC 122 may be configured to shut-off the auto-valves 112 in response to receiving a signal from the leak detection rope 126. Additionally, the SHC 122 may also be configured to communicate the leak detection to the CDU 130 as well as to a system managing the workload on the IT rack 102. In one implementation, the SHC 122 may generate an alarm upon receiving a leak detection signal so that the one or more manual valves may be used to manually close the flow of coolant through the hoses 104, 106.

The CDU 130 may be configured to manage flow rate through the hoses 104, 106 of different IT racks at different levels. For example, if there is detection of leak in the IT rack 102, the CDU may decrease the rate of flow of coolant to the IT rack 102 but increase the rate of flow of coolant through other IT racks connected thereto, in anticipation of increased workloads on the other IT racks. Alternatively, the SHC 122 of the IT rack 102 may be configured to directly communicate to the SHC configured on other IT racks. In such an implementation, when the SHC 122 may decrease the flow rate of coolant to the IT rack 102 by adjusting the auto-valves 112, an SHC of another IT rack may increase the rate of coolant to such another IT rack.

Providing various sensors 108 located on the hoses 104, 106 of the IT rack 102 such that they are communicatively connected to the SHC 122 allows the coolant system 100 to manage the delivery of coolant to the IT rack 102 in response to changes in coolant flow parameters and therefore increases the reliability of the coolant system 100 and the health of the IT rack 102. Additionally, the coolant system 100 provides additional advantages by allowing the SHC 122 to instantaneously turn-off coolant supply by controlling the auto-valves 112. Furthermore, by configuring the SHC 122 of various IT racks are in communication with each other and with the CDU 130, the coolant system 100 also allows any cloud or server system using these IT racks to more efficiently distribute the workload among the IT racks in response to change in change in coolant delivery parameters of one of such IT racks.

Another advantage provided by the disclosed smart hose kit, including combination of sensors 108 located on hoses 104, 106 in communication with the SHC 122, is that it moves the burdens of controlling liquid cooling from the IT racks 102 to the hoses 104, 106. Furthermore, such smart hose kits allow for providing standardization of the smart hose kit to be used for all liquid cooled IT racks so as to simplify IT rack design, reduce time-to-market (TTM), and reduce costs associated with their maintenance.

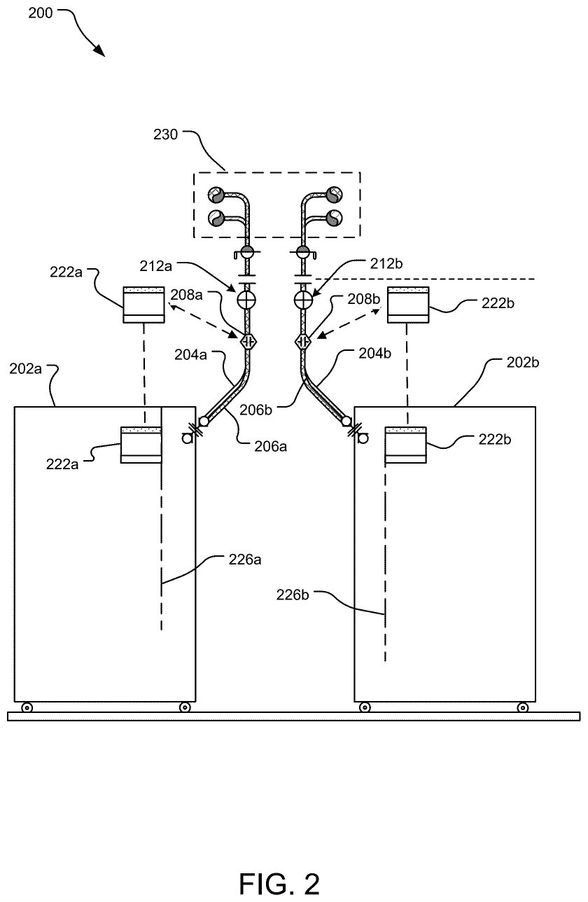

FIG. 2 illustrates an implementation of the coolant system 200 for the computing system racks. Specifically, the coolant system 200 illustrates multiple IT racks, in this case two IT racks 202a and 202b that are connected to a coolant supply system using hoses. Each of the IT racks 202 are connected to a coolant distribution unit (CDU) 230. Specifically, the IT rack 202a is connected to the CDU 230 by hoses 204a, 206a whereas the IT rack 202b is connected to the CDU 230 by hoses 204b, 206b. Furthermore, each of the IT tacks 202 are configured to have a smart hose controller (SHC) 222 that is communicatively connected to sensors 208 located on the hoses thereof. Thus, the SHC 222a on the IT rack 202a is communicatively connected to sensors 208a located on hoses 204a and 206a, wherein the SHC 222b on the IT rack 202b is communicatively connected to sensors 208b located on hoses 204b and 206b.

The sensors 208 may include a temperature sensor, a pressure sensor, a flow rate sensor, etc. In one implementation, the sensors 208 may be configured to wirelessly communicate the measured coolant parameters to the SHCs 222. The SHCs 222 may be implemented on the IT racks 202 or they may be configured outside of the IT racks 202 and close to the sensors 208. Furthermore, each of the SHCs 222 may be configured to receive power from the IT racks 202 and to provide power to the sensors 208. Each of the IT racks 202 may also include a leak detector 226 that detects leak of coolant in the IT rack and communicate such detection to the respective SHC 222 implemented on the IT rack 202.

The SHCs 222 are configured to analyze the measured coolant parameters received from the sensors 208 and to control the auto-valves 212. Thus, if the analysis of the temperatures as measured by the sensors 208a indicates that the IT rack 202a is heating up, the SHC 222a may open an auto-valve 212a on the incoming hose 204a to allow for higher coolant flow through the IT rack 202a. Alternatively, if the leak detector 226a generates a signal indicating a coolant leak in the IT rack 202a, the SHC 222a may shut-off the auto-valve 212a to prevent any further damage to the IT rack 202a.

Additionally, the SHCs 222a and 222b may be communicatively connected to each other such that they can communicate the coolant parameters measured by the sensors 208a and 208b with each other. Additionally, the SHCs 222a and 222b may also communicate the coolant parameters measured by the sensors 208a and 208b with the CDU 230. The coolant system 200 may be configured to provide communication between the SHCs 222 implemented on different racks 202. For example, if the IT rack 202s needs to have decreased workload due to coolant leak, the SHC 222b of the IT rack 202b may increase the coolant flow by controlling the auto-valve 212b such that the IT rack 202b is capable of taking up additional workload.

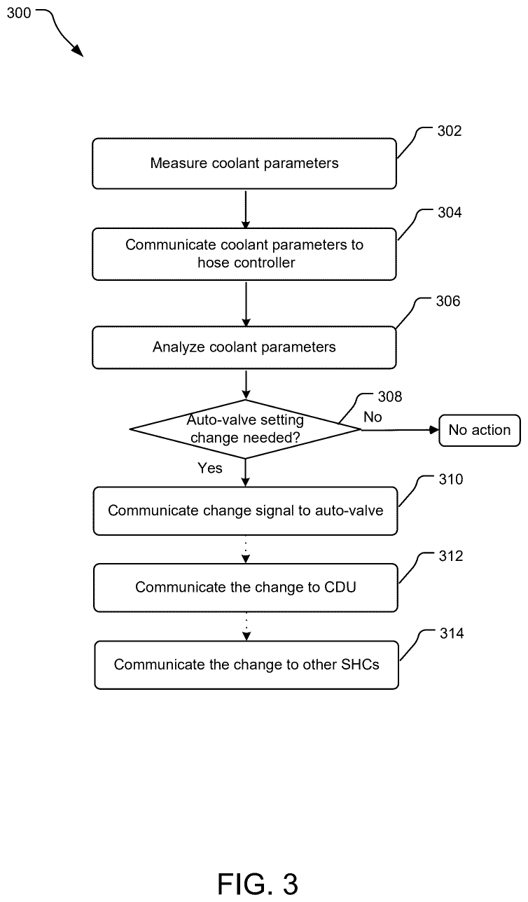

FIG. 3 illustrates operations 300 of the cooling system disclosed herein. One or more of the operations 300 may be implemented on various components of the coolant system disclosed herein, including one or more sensors, a smart hose controller (SHC), etc. An operation 302 measures various parameters of the coolants running through hoses of the coolant system. For example, in one implementation, the temperature, the pressure, and the flow rate of the coolant circulating through the incoming hose and the outgoing hose of the coolant system may be measured. However, in an alternative implementation, the coolant parameters of the coolant circulating through only one of the incoming hose and the outgoing hose of the coolant system may be measured.

Subsequently, an operation 304 communicates the coolant parameters to a hose controller. In one implementation, the sensors may communicate the coolant parameters via a wired connection to the hose controller. Alternatively, the sensors may communicate the coolant parameters using a wireless protocol, such as Bluetooth, Bluetooth LE, to the hose controller. The hose controller may be configured on an IT rack or on a hose in proximity to the sensors. Upon receiving the coolant parameters, an operation 306 analyzes the coolant parameters. For example, such comparison may be done by a hose controller. As an example, the analysis at operation 306 may include filtering the measured parameters to determine if the filtered value of the parameters is above or below a threshold. Alternatively, the change in the operating parameter over a period of time may be calculated as part of the analysis. In another implementation the analysis may include determining the difference between operating parameters collected from the sensor on the incoming hose and the operating parameters collected from the sensor on the outgoing hose.

In response to the analysis, an operation 308 determines if any changes are required to be made to the auto-valve settings on either of the incoming hose and the outgoing hose. If the operation 308 determines that such changes are necessary, an operation 310 communicates the change signal to one or both auto-valves on the incoming hose and the outgoing hose. Subsequently and optionally, an operation 312 communicates the changes made to the flow rate in the incoming hose and/or the outgoing hose to a CDU. Furthermore, an operation 314 may also communicate the information about such changes to the hose controllers of other IT racks.

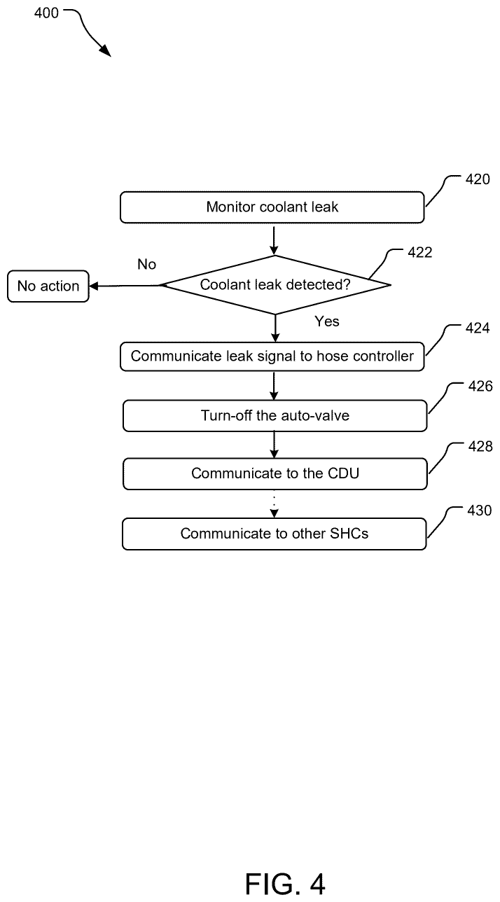

FIG. 4 illustrates alternative operations 400 of the cooling system disclosed herein. One or more of the operations 400 may be implemented on various components of the coolant system disclosed herein, including one or more sensors, leak detectors, a smart hose controller (SHC), etc. An operation 420 monitors the IT rack for potential leak of coolant. For example, monitoring the leak may include using sensors that detect presence of coolant or moisture between its electrodes and generating a signal if any coolant or moisture is detected that may generate electrical current between the electrodes. An operation 422 analyzes the output signal from such sensors to determine if a leak was detected. For example, the operation 422 may compare the output signal form the leak detector to a threshold and if the output signal is above the threshold, it may determine that there is a leak in the IT rack.

In response to detecting a leak, an operation 424 communicates the leak signal to a hose controller. For example, such communication may be either wireless or over a wired communication line. At operation 426, the hose controller may generate a communication to the auto-valves on one or both of an incoming and outgoing hose of the coolant system to turn-off the auto-valve(s). Furthermore, an operation 428 communicates the decision to turn-off the auto-valves and the detection of coolant leak to a CDU. Subsequently and optionally, an operation 430 communicates the change decision to turn-off the auto-valves and the detection of coolant leak to SHCs on other IT racks.

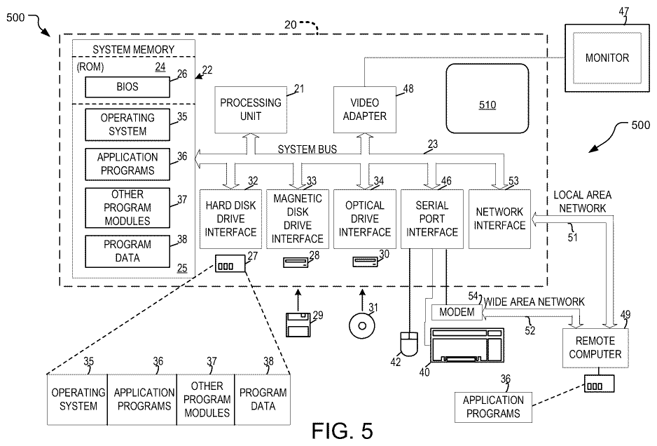

FIG. 5 illustrates an example system 500 that may be useful in implementing the cooling management disclosed herein. The example hardware and operating environment of FIG. 5 for implementing the described technology includes a computing device, such as a general-purpose computing device in the form of a computer 20, a mobile telephone, a personal data assistant (PDA), a tablet, smart watch, gaming remote, or other type of computing device. In the implementation of FIG. 5, for example, the computer 20 includes a processing unit 21, a system memory 22, and a system bus 23 that operatively couples various system components including the system memory 22 to the processing unit 21. There may be only one or there may be more than one processing unit 21, such that the processor of a computer 20 comprises a single central-processing unit (CPU), or a plurality of processing units, commonly referred to as a parallel processing environment. The computer 20 may be a conventional computer, a distributed computer, or any other type of computer; the implementations are not so limited.

In the example implementation of the computing system 500, the computer 20 also includes a hose controller 510 that may be used in the coolant management system disclosed herein.

The system bus 23 may be any of several types of bus structures including a memory bus or memory controller, a peripheral bus, a switched fabric, point-to-point connections, and a local bus using any of a variety of bus architectures. The system memory may also be referred to as simply the memory, and includes read-only memory (ROM) 24 and random-access memory (RAM). A basic input/output system (BIOS) 26, containing the basic routines that help to transfer information between elements within the computer 20, such as during start-up, is stored in ROM 24. The computer 20 further includes a hard disk drive 27 for reading from and writing to a hard disk, not shown, a magnetic disk drive 28 for reading from or writing to a removable magnetic disk 29, and an optical disk drive 30 for reading from or writing to a removable optical disk 31 such as a CD ROM, DVD, or other optical media.

In one implementation, one or more instructions of the hose controller 510 that may be used in the coolant management system may be stored in the memory of the computer 20, such as the read-only memory (ROM) 24 and random-access memory (RAM) 25, etc.

The hard disk drive 27, magnetic disk drive 28, and optical disk drive 30 are connected to the system bus 23 by a hard disk drive interface 32, a magnetic disk drive interface 33, and an optical disk drive interface 34, respectively. The drives and their associated tangible computer-readable media provide nonvolatile storage of computer-readable instructions, data structures, program modules and other data for the computer 20. It should be appreciated by those skilled in the art that any type of tangible computer-readable media may be used in the example operating environment.

A number of program modules may be stored on the hard disk, magnetic disk 29, optical disk 31, ROM 24, or RAM 25, including an operating system 35, one or more application programs 36, other program modules 37, and program data 38. A user may generate reminders on the personal computer 20 through input devices such as a keyboard 40 and pointing device 42. Other input devices (not shown) may include a microphone (e.g., for voice input), a camera (e.g., for a natural user interface (NUI)), a joystick, a game pad, a satellite dish, a scanner, or the like. These and other input devices are often connected to the processing unit 21 through a serial port interface 46 that is coupled to the system bus 23, but may be connected by other interfaces, such as a parallel port, game port, or a universal serial bus (USB). A monitor 47 or other type of display device is also connected to the system bus 23 via an interface, such as a video adapter 48. In addition to the monitor, computers typically include other peripheral output devices (not shown), such as speakers and printers.

The computer 20 may operate in a networked environment using logical connections to one or more remote computers, such as remote computer 49. These logical connections are achieved by a communication device coupled to or a part of the computer 20; the implementations are not limited to a particular type of communications device. The remote computer 49 may be another computer, a server, a router, a network PC, a client, a peer device, or other common network node, and typically includes many or all of the elements described above relative to the computer 20. The logical connections depicted in FIG. 5 include a local-area network (LAN) 51 and a wide-area network (WAN) 52. Such networking environments are commonplace in office networks, enterprise-wide computer networks, intranets, and the Internet, which are all types of networks.

When used in a LAN-networking environment, the computer 20 is connected to the local area network 51 through a network interface or adapter 53, which is one type of communications device. When used in a WAN-networking environment, the computer 20 typically includes a modem 54, a network adapter, a type of communications device, or any other type of communications device for establishing communications over the wide area network 52. The modem 54, which may be internal or external, is connected to the system bus 23 via the serial port interface 46. In a networked environment, program engines depicted relative to the personal computer 20, or portions thereof, may be stored in the remote memory storage device. It is appreciated that the network connections shown are example and other means of communications devices for establishing a communications link between the computers may be used.

In an example implementation, software, or firmware instructions for the hose controller 510 that may be used in the coolant management system may be stored in system memory 22 and/or storage devices 29 or 31 and processed by the processing unit 21. The hose controller 510 and data used by the hose controller 510 may be stored in system memory 22 and/or storage devices 29 or 31 as persistent data-stores.

In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include wired media such as a wired network or direct-wired connection, and wireless media such as acoustic, RF, infrared, and other wireless media.

Some implementations of the coolant management system may comprise an article of manufacture. An article of manufacture may comprise a tangible storage medium to store logic. Examples of a storage medium may include one or more types of computer-readable storage media capable of storing electronic data, including volatile memory or non-volatile memory, removable or non-removable memory, erasable or non-erasable memory, writeable or re-writeable memory, and so forth. Examples of the logic may include various software elements, such as software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. In one implementation, for example, an article of manufacture may store executable computer program instructions that, when executed by a computer, cause the computer to perform methods and/or operations in accordance with the described implementations. The executable computer program instructions may include any suitable type of code, such as source code, compiled code, interpreted code, executable code, static code, dynamic code, and the like. The executable computer program instructions may be implemented according to a predefined computer language, manner, or syntax, for instructing a computer to perform a certain function. The instructions may be implemented using any suitable high-level, low-level, object-oriented, visual, compiled and/or interpreted programming language.

The coolant system disclosed herein may include a variety of tangible computer-readable storage media and intangible computer-readable communication signals. Tangible computer-readable storage can be embodied by any available media that can be accessed by the coolant management system disclosed herein and includes both volatile and nonvolatile storage media, removable and non-removable storage media. Tangible computer-readable storage media excludes intangible and transitory communications signals and includes volatile and nonvolatile, removable, and non-removable storage media implemented in any method or technology for storage of information such as computer readable instructions, data structures, program modules or other data. Tangible computer-readable storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other tangible medium which can be used to store the desired information and which can be accessed by the coolant management system disclosed herein. In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals moving through wired media such as a wired network or direct-wired connection, and signals moving through wireless media such as acoustic, RF, infrared, and other wireless media.

A system disclosed herein includes a hose configured to deliver coolant to and from a first computing system rack, one or more sensors configured to measure one or more parameters of the coolant flowing through the hose and to communicate the one or more measured parameters to a hose controller, and an auto-valve configured on the hose to control the flow of the coolant through the hose, wherein the hose controller is configured to analyze the one or more parameters of the coolant flowing through the hose and to control the auto-valve based on the analysis of the one or more parameters of the coolant flowing through the hose.

A coolant management system for a computing system rack disclosed herein includes a hose configured to deliver coolant to and from a first computing system rack, one or more sensors configured to measure one or more parameters of the coolant flowing through the hose and to communicate the one or more measured parameters to a hose controller, wherein the one or more sensors include (a) a temperature sensor to determine a temperature of the coolant flowing through the hose, (b) a flow sensor configured to determine flow level of the coolant flowing through the hose, and (c) a pressure sensor configured to determine pressure of the coolant flowing through the hose, and an auto-valve configured on the hose to control the flow of coolant through the hose, wherein the hose controller is configured to analyze the one or more parameters of the coolant flowing through the hose and to control the auto-valve based on the analysis of the one or more parameters of the coolant flowing through the hose.

A hose control kit for a hose configured to deliver coolant to and from a computing system rack, the hose control kit including one or more sensors configured to measure one or more parameters of the coolant flowing through the hose and to communicate the one or more measured parameters to a hose controller, wherein the one or more sensors include (a) a temperature sensor to determine a temperature of the coolant flowing through the hose, (b) a flow sensor configured to determine flow level of the coolant flowing through the hose, and (c) a pressure sensor configured to determine pressure of the coolant flowing through the hose, and an auto-valve configured on the hose to control the flow of coolant through the hose, wherein the hose controller is configured to analyze the one or more parameters of the coolant flowing through the hose and to control the auto-valve based on the analysis of the one or more parameters of the coolant flowing through the hose.

The implementations described herein are implemented as logical steps in one or more computer systems. The logical operations may be implemented (1) as a sequence of processor-implemented steps executing in one or more computer systems and (2) as interconnected machine or circuit modules within one or more computer systems. The implementation is a matter of choice, dependent on the performance requirements of the computer system being utilized. Accordingly, the logical operations making up the implementations described herein are referred to variously as operations, steps, objects, or modules. Furthermore, it should be understood that logical operations may be performed in any order, unless explicitly claimed otherwise or a specific order is inherently necessitated by the claim language. The above specification, examples, and data, together with the attached appendices, provide a complete description of the structure and use of exemplary implementations.

As utilized herein, terms “component,” “system,” “interface,” and the like are intended to refer to a computer-related entity, either hardware, software (e.g., in execution), and/or firmware. For example, a component can be a process running on a processor, a processor, an object, an executable, a program, and/or a computer. By way of illustration, both an application running on a server and the server can be a component. One or more components can reside within a process and a component can be localized on one computer and/or distributed between two or more computers.

The claimed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the claimed subject matter may be practiced without these specific details. In other instances, well-known structures and devices are shown in block diagram form in order to facilitate describing the subject innovation.

What is claimed is:

1. A system, comprising:
a hose configured to deliver coolant to and from a first computing system rack;
one or more sensors configured to measure one or more parameters of the coolant flowing through the hose and to communicate the one or more measured parameters to a hose controller; and
an auto-valve configured on the hose to control the flow of the coolant through the hose,
wherein the hose controller is configured to analyze the one or more parameters of the coolant flowing through the hose and to control the auto-valve based on the analysis of the one or more parameters of the coolant flowing through the hose.

2. The system of claim 1, wherein the one or more sensors include (a) a temperature sensor to determine a temperature of the coolant flowing through the hose, (b) a flow sensor configured to determine flow level of the coolant flowing through the hose, and (c) a pressure sensor configured to determine pressure of the coolant flowing through the hose.

3. The system of claim 1, wherein the hose controller is configured on the first computing system rack and is configured to provide power to the one or more sensors.

4. The system of claim 1, wherein the hose controller is configured on the hose outside the first computing rack and is configured to receive power from first computing rack and to provide power to the one or more sensors.

5. The system of claim 1, wherein the one or more sensors communicates with the hose controller using a wireless communication protocol.

6. The system of claim 5, wherein the wireless protocol is at least one of Bluetooth, Bluetooth LE, ZigBee, and Z-Wave.

7. The system of claim 1, further comprising a leak detector configured to detect a coolant leak in the first computing system rack and to communicate the coolant leak to the hose controller, wherein the hose controller is configured to shut-off the auto-valve in response to the coolant leak.

8. The system of claim 1, wherein the hose controller is configured to communicate a flow level of the coolant flowing through the hose of the first computing system rack with a coolant distribution unit (CDU), wherein the CDU is configured to change a supply level of coolant to the hose based on pressure of the coolant flowing through the hose.

9. The system of claim 8, wherein the CDU is configured to adjust flow level of coolant flowing through a hose of a second computing system rack based on the pressure of the coolant flowing through the hose of the first computing system rack.

10. The system of claim 1, wherein the hose controller is further configured to communicate the one or more measured coolant parameters of the first computing system rack to another hose controller configured on a second computing system rack.

11. A coolant management system for a computing system rack, comprising:
a hose configured to deliver coolant to and from a first computing system rack;
one or more sensors configured to measure one or more parameters of the coolant flowing through the hose and to communicate the one or more measured parameters to a hose controller, wherein the one or more sensors include (a) a temperature sensor to determine a temperature of the coolant flowing through the hose, (b) a flow sensor configured to determine flow level of the coolant flowing through the hose, and (c) a pressure sensor configured to determine pressure of the coolant flowing through the hose; and
an auto-valve configured on the hose to control the flow of coolant through the hose,
wherein the hose controller is configured to analyze the one or more parameters of the coolant flowing through the hose and to control the auto-valve based on the analysis of the one or more parameters of the coolant flowing through the hose.

12. The coolant management system of claim 11, wherein the hose controller is configured on the first computing system rack and is configured to provide power to the one or more sensors.

13. The coolant management system of claim 11, wherein the one or more sensors communicates with the hose controller using a wireless communication protocol.

14. The coolant management system of claim 11, further comprising a leak detector configured to detect a coolant leak in the first computing system rack and to communicate the coolant leak to the hose controller, wherein the hose controller is configured to shut-off the auto-valve in response to the coolant leak.

15. The coolant management system of claim 11, wherein the hose controller is configured to communicate a flow level of the coolant flowing through the hose of the first computing system rack with a coolant distribution unit (CDU), wherein the CDU is configured to change a supply of coolant to the hose based on the pressure of the coolant flowing through the hose.

16. The coolant management system of claim 15, wherein the CDU is configured to adjust flow level of coolant flowing through a hose of a second computing system rack based on the pressure of the coolant flowing through the hose of the first computing system rack.

17. A hose control kit for a hose configured to deliver coolant to and from a computing system rack, the hose control kit comprising:
one or more sensors configured to measure one or more parameters of the coolant flowing through the hose and to communicate the one or more measured parameters to a hose controller, wherein the one or more sensors include (a) a temperature sensor to determine a temperature of the coolant flowing through the hose, (b) a flow sensor configured to determine flow level of the coolant flowing through the hose, and (c) a pressure sensor configured to determine pressure of the coolant flowing through the hose; and
an auto-valve configured on the hose to control the flow of coolant through the hose,
wherein the hose controller is configured to analyze the one or more parameters of the coolant flowing through the hose and to control the auto-valve based on the analysis of the one or more parameters of the coolant flowing through the hose.

18. The hose control kit of claim 17, wherein the one or more sensors communicates with the hose controller using a wireless communication protocol.

19. The hose control kit of claim 17, further comprising a leak detector configured to detect a coolant leak in the computing system rack and to communicate the coolant leak to the hose controller, wherein the hose controller is configured to shut-off the auto-valve in response to the coolant leak.

20. The hose control kit of claim 17, wherein the hose controller is further configured to communicate the one or more measured coolant parameters of the computing system rack to another hose controller configured on a second computing system rack.
